(19) United States
(12) Patent Application Publication
(10) Pub. No.: US 2023/0403950 A1
(43) Pub. Date: Dec. 14, 2023

(54) SEMICONDUCTOR DEVICE

(71) Applicant: ROHM CO., LTD., Kyoto (JP)

(72) Inventor: Yushi SEKIGUCHI, Kyoto (JP)

(73) Assignee: ROHM CO., LTD., Kyoto (JP)

(21) Appl. No.: 18/326,422

(22) Filed: May 31, 2023

(30) Foreign Application Priority Data
Jun. 8, 2022 (JP) 2022-092889

(51) Int. Cl. H10N 52/00; H10N 52/01; H10N 52/80

(52) U.S. Cl. CPC H10N 52/101; H10N 52/01; H10N 52/80; G01R 33/077

(57) ABSTRACT

A semiconductor device, includes: a semiconductor substrate having first and second main surfaces; and first and second polysilicon layers doped with impurity, wherein the semiconductor substrate includes a diffusion layer doped with impurity, the diffusion layer is located between the first main surface and the second main surface, first and second grooves are formed on the first main surface in spaced-apart relationship along a first direction in a plan view, the first and second grooves each extend along a second direction orthogonal to the first direction in a plan view and extend toward the second main surface to reach the diffusion layer in a cross-sectional view orthogonal to the second direction, the first and second polysilicon layers are embedded in the first and second grooves, respectively, and lower ends of the first and second polysilicon layers are electrically connected to each other by the diffusion layer.

### CROSS-REFERENCE TO RELATED APPLICATION

This application is based upon and claims the benefit of priority from Japanese Patent Application No. 2022-092889, filed on Jun. 8, 2022, the entire contents of which are incorporated herein by reference.

### TECHNICAL FIELD

The present disclosure relates to a semiconductor device.

### BACKGROUND

In the related art, a semiconductor device is disclosed. The semiconductor device disclosed in the related art includes a semiconductor substrate. The semiconductor substrate has a first main surface and a second main surface. The semiconductor substrate has a first well region, a first contact region, a second contact region, and a second well region. The first well region, the first contact region, the second contact region, and the second well region constitute a vertical Hall element.

The first well region is formed on the first main surface. A conductivity type of the first well region is a p-type. The first contact region and the second contact region are formed on the first main surface. A conductivity type of the first contact region and a conductivity type of the second contact region are an n-type. The first well region is located between the first contact region and the second contact region in a cross-sectional view. A lower end of the first well region is closer to the second main surface than a lower end of the first contact region and a lower end of the second contact region. The second well region is formed on the first main surface so as to surround the first well region, the first contact region and the second contact region in a cross-sectional view. That is, the lower end of the second well region is closer to the second main surface than the lower end of the first well region. An impurity concentration in the first contact region and an impurity concentration in the second contact region are higher than an impurity concentration in the second well region.

In the semiconductor device disclosed in the related art, a current flows downward from the first contact region. This current flows between the lower end of the first well region and the lower end of the second well region and then flows upward to the second contact region. Lorentz force from a magnetic field parallel to the first main surface bends a path of the current flowing downward from the first contact region and a path of the current flowing upward to the second contact region. The semiconductor device disclosed in the related art may detect a magnetic field based on a change in resistance value caused by the bending of the current paths.

In the semiconductor device disclosed in the related art, the second well region is formed by implanting ions into the first main surface and then annealing the semiconductor substrate to thermally diffuse the implanted ions toward the second main surface. As a result, the impurity concentration in the second well region becomes lower toward the second main surface. Therefore, in the semiconductor device disclosed in the related art, the resistance value of the second well region may vary along a thickness direction of the semiconductor substrate, and a magnetic field detection sensitivity may also vary along the thickness direction of the semiconductor substrate. In addition, in the semiconductor device disclosed in the related art, due to the above-described annealing, the second well region is expanded not only in a direction facing the second main surface but also in a lateral direction (a direction orthogonal to a direction facing from the first main surface to the second main surface). This makes it difficult to reduce an area of a vertical Hall element.

### SUMMARY

Some embodiments of the present disclosure provide a semiconductor device including a vertical Hall element with suppressed variations in a magnetic detection sensitivity.

According to an embodiment of the present disclosure, a semiconductor device includes: a semiconductor substrate having a first main surface and a second main surface; and a first polysilicon layer and a second polysilicon layer doped with an impurity. The semiconductor substrate includes a diffusion layer doped with an impurity. The diffusion layer is located between the first main surface and the second main surface. A first groove and a second groove are formed on the first main surface in a spaced-apart relationship along a first direction in a plan view. Each of the first groove and the second groove extends along a second direction orthogonal to the first direction in a plan view and extends toward the second main surface so as to reach the diffusion layer in a cross-sectional view orthogonal to the second direction. The first polysilicon layer and the second polysilicon layer are embedded in the first groove and the second groove, respectively. A lower end of the first polysilicon layer and a lower end of the second polysilicon layer are electrically connected to each other by the diffusion layer.

### BRIEF DESCRIPTION OF DRAWINGS

The accompanying drawings, which are incorporated in and constitute a part of the specification, illustrate embodiments of the present disclosure.

FIG. 1 is a schematic block diagram of a semiconductor device.

FIG. 2 is a plan view of the semiconductor device.

FIG. 3 is a cross-sectional view taken along line III-III in FIG. 2.

FIG. 4 is a cross-sectional view taken along line IV-IV in FIG. 2.

FIG. 5 is a cross-sectional view taken along line V-V in FIG. 2.

FIG. 6 is a diagram showing a process of manufacturing the semiconductor device.

FIG. 7 is a cross-sectional view for explaining a diffusion layer formation step S1.

FIG. 8 is a cross-sectional view for explaining an epitaxial growth step S2.

FIG. 9 is a cross-sectional view for explaining a first groove formation step S3.

FIG. 10 is a cross-sectional view for explaining a first insulating film formation step S4.

FIG. 11 is a cross-sectional view for explaining a polysilicon layer formation step S5.

FIG. 12 is a cross-sectional view for explaining a first ion implantation step S6.

FIG. 13 is a cross-sectional view for explaining a second groove formation step S7.

FIG. 14 is a cross-sectional view for explaining a second insulating film formation step S8.

FIG. 15 is a cross-sectional view for explaining a gate insulating film formation step S9.

FIG. 16 is a cross-sectional view for explaining a gate formation step S10.

FIG. 17 is a cross-sectional view for explaining a second ion implantation step S11.

FIG. 18 is a cross-sectional view for explaining a sidewall spacer formation step S12.

FIG. 19 is a cross-sectional view for explaining a third ion implantation step S13.

FIG. 20 is a cross-sectional view for explaining an interlayer insulating film formation step S15.

FIG. 21 is a cross-sectional view for explaining a contact plug formation step S16.

FIG. 22 is a plan view of a semiconductor device.

FIG. 23 is a cross-sectional view taken along line XXIII-XXIII in FIG. 22.

FIG. 24 is a cross-sectional view taken along line XXIV-XXIV in FIG. 22.

### DETAILED DESCRIPTION

Details of embodiments of the present disclosure will be described with reference to the drawings. In the drawings described below, the same or corresponding parts are denoted by the same reference numerals, and the redundant description thereof will not be repeated.

### First Embodiment

A semiconductor device according to a first embodiment of the present disclosure will be described. The semiconductor device according to the first embodiment is referred to as a semiconductor device 100.

### <Structure of Semiconductor Device 100>

A structure of the semiconductor device 100 will be described below.

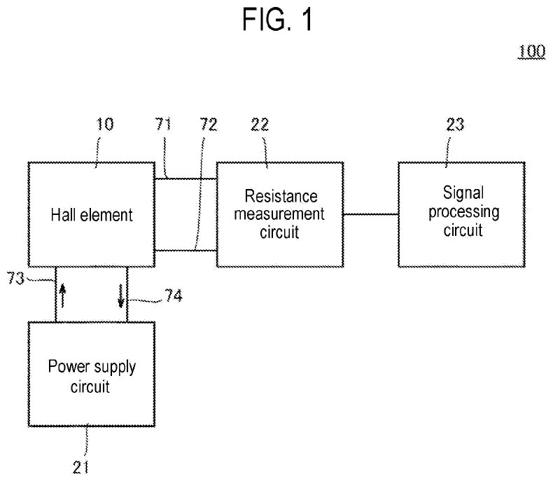

FIG. 1 is a schematic block diagram of the semiconductor device 100. As shown in FIG. 1, the semiconductor device 100 includes a Hall element 10, a power supply circuit 21, a resistance measurement circuit 22, and a signal processing circuit 23. The power supply circuit 21 supplies a constant current to the Hall element 10 (see the arrow in FIG. 1). The resistance measurement circuit 22 measures resistance values of polysilicon layers 31 and 32, which will be described later. The signal processing circuit 23 performs a signal processing for detecting a magnetic field applied to the Hall element 10 based on changes in the resistance values of the polysilicon layers 31 and 32 measured by the resistance measurement circuit 22.

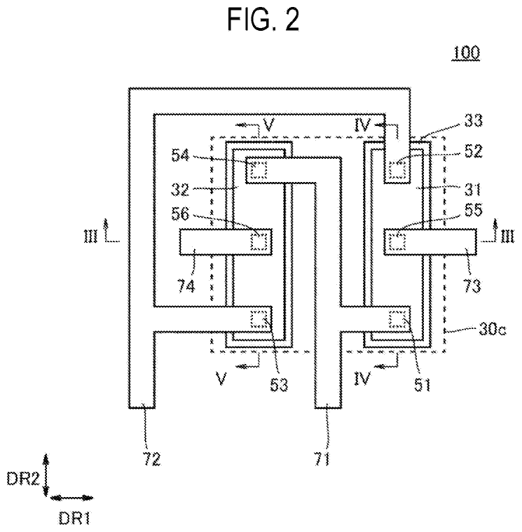

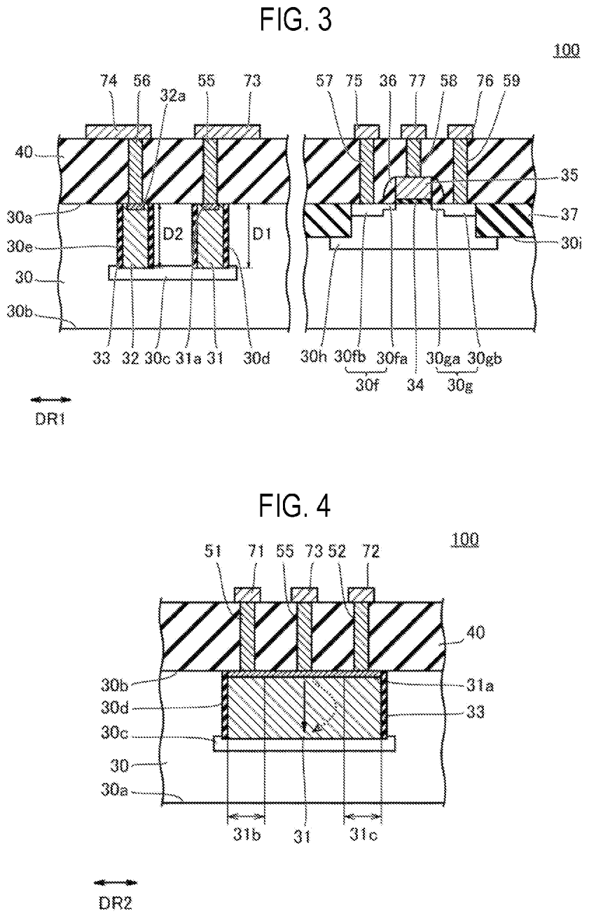

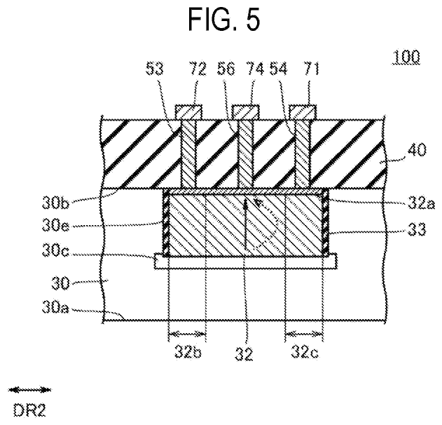

FIG. 2 is a plan view of the semiconductor device 100. In FIG. 2, illustration of an interlayer insulating film 40 is omitted. FIG. 3 is a cross-sectional view taken along line III-III in FIG. 2. FIG. 4 is a cross-sectional view taken along line IV-IV in FIG. 2. FIG. 5 is a cross-sectional view taken along line V-V in FIG. 2. As shown in FIGS. 2 to 5, the semiconductor device 100 includes a semiconductor substrate 30, polysilicon layers 31 and 32, an insulating film 33, a gate insulating film 34, a gate 35, a sidewall spacer 36, and an insulating film 37.

The semiconductor device 100 further includes an interlayer insulating film 40, a contact plug 51, a contact plug 52, a contact plug 53, a contact plug 54, a contact plug 55, a contact plug 56, a contact plug 57, a contact plug 58, a contact plug 59, a wiring 71, a wiring 72, a wiring 73, a wiring 74, a wiring 75, a wiring 76, and a wiring 77.

The semiconductor substrate 30 is made of, for example, monocrystalline silicon (Si). The semiconductor substrate 30 is doped with an impurity so that a conductivity type thereof is, for example, a first conductivity type. The first conductivity type is, for example, a p-type. The semiconductor substrate 30 has a main surface 30a and a main surface 30b. The main surface 30a and the main surface 30b are end surfaces of the semiconductor substrate 30 in a thickness direction thereof. The main surface 30b is an opposite surface of the main surface 30a.

The semiconductor substrate 30 includes a diffusion layer 30c. The diffusion layer 30c is doped with an impurity so that a conductivity type thereof is, for example, a second conductivity type. The second conductivity type is a conductivity type opposite to the first conductivity type. In a case where the first conductivity type is a p-type, the second conductivity type is an n-type. The diffusion layer 30c is located between the main surface 30a and the main surface 30b. The diffusion layer 30c extends in a plane orthogonal to the thickness direction of the semiconductor substrate 30. The diffusion layer 30c has, for example, a rectangular shape in a plan view.

A groove 30d and a groove 30e are formed on the main surface 30a. The groove 30d and the groove 30e are arranged at an interval along a first direction DR1 in a plan view. The plan view refers to a view in which the semiconductor device 100 is viewed in a normal direction of the main surface 30a. Each of the grooves 30d and 30e extends along a second direction DR2 in a plan view. The second direction DR2 is a direction orthogonal to the first direction DR1. In a cross-sectional view orthogonal to the second direction DR2, each of the grooves 30d and 30e extends toward the main surface 30b. A lower end of the groove 30d and a lower end of the groove 30e reach the diffusion layer 30c.

A depth of the groove 30d is defined as a depth D1, and a depth of the groove 30e is defined as a depth D2. The depth D1 and the depth D2 are preferably 10 μm or more and 30 μm or less. The depth D1 and the depth D2 may be 10 μm or more and 20 μm or less.

The semiconductor substrate 30 includes a source region 30f, a drain region 30g, and a well region 30h. The source region 30f and the drain region 30g are formed on the main surface 30a in a spaced-apart relationship with each other. The source region 30f includes a first portion 30fa and a second portion 30fb. The first portion 30fa is closer to the drain region 30g than the second portion 30fb. The drain region 30g includes a first portion 30ga and a second portion 30gb. The first portion 30ga is closer to the source region 30f than the second portion 30gb. The well region 30h is formed on the main surface 30a to surround the source region 30f and the drain region 30g.

The source region 30f and the drain region 30g are doped with an impurity so as to have the same conductivity type. The well region 30h is doped with an impurity so that a conductivity type thereof is opposite to that of the source region 30f and the drain region 30g. For example, a conductivity type of the source region 30f and a conductivity type of the drain region 30g are the second conductivity type, and the conductivity type of the well region 30h is the first conductivity type. An impurity concentration in the first portion 30fa is higher than an impurity concentration in the second portion 30fb. The impurity concentration in the first portion 30ga is higher than the impurity concentration in the second portion 30gb. That is, the source region 30f and the drain region 30g have an LDD (Lightly Doped Diffusion) structure.

A groove 30i is formed on the main surface 30a. The groove 30i surrounds the well region 30h in a plan view. The groove 30i extends toward the main surface 30b in a cross-sectional view orthogonal to an extension direction of the groove 30i. In addition, for example, a depth of the groove 30i is smaller than the depth D1 and the depth D2.

The polysilicon layer 31 and the polysilicon layer 32 are embedded in the grooves 30d and 30e, respectively. The polysilicon layer 31 and the polysilicon layer 32 are doped with impurity so that conductivity types thereof are, for example, the second conductivity type. A lower end of the polysilicon layer 31 and a lower end of the polysilicon layer 32 are electrically connected to the diffusion layer 30c.

The impurity concentration is uniform in each of the polysilicon layers 31 and 32. That is, in each of the polysilicon layers 31 and 32, minimum and maximum impurity concentrations are 0.8 times or more and 1.2 times or less the average impurity concentration, respectively. The diffusion layer 30c, the polysilicon layer 31, and the polysilicon layer 32 constitute the Hall element 10. The Hall element 10 is a vertical Hall element capable of detecting a magnetic field in a direction parallel to the main surface 30a. For example, the impurity concentrations in the polysilicon layers 31 and 32 are lower than the impurity concentration in the diffusion layer 30c. The impurity concentrations in the polysilicon layers 31 and 32 are measured by, for example, SCM (Scanning Capacitance Microscope) analysis.

A contact region 31a is formed at an upper end of the polysilicon layer 31. A contact region 32a is formed at an upper end of the polysilicon layer 32. An impurity concentration in the contact region 31a is higher than the impurity concentration in regions other than the contact region 31a. An impurity concentration in the contact region 32a is higher than the impurity concentration in regions other than the contact region 32a. An insulating film 33 is interposed between an inner wall surface of the groove 30d and the polysilicon layer 31 and between an inner wall surface of the groove 30e and the polysilicon layer 32. The insulating film 33 is made of, for example, silicon oxide.

The gate insulating film 34 is disposed on a portion of the main surface 30a between the source region 30f and the drain region 30g. The gate insulating film 34 is made of, for example, silicon oxide. The gate 35 is arranged on the gate insulating film 34. From another point of view, the gate 35 faces the portion of the well region 30h (i.e., the channel region) between the source region 30f and the drain region 30g in an insulated state. The source region the drain region 30g, the well region 30h, the gate insulating film 34, and the gate 35 constitute a transistor. This transistor forms parts of the power supply circuit 21, the resistance measurement circuit 22, and the signal processing circuit 23.

The sidewall spacer 36 is arranged on the first portions 30fa and 30ga so as to be in contact with a side surface of the gate 35. The sidewall spacer 36 is made of, for example, silicon nitride. The insulating film 37 is embedded in the groove 30i. One transistor is insulated and separated from other transistors by the insulating film 37. That is, the groove 30i and the insulating film 37 have an STI (Shallow Trench Isolation) structure. However, a LOCOS (Local Oxidation of Silicon) structure may be used as an element isolation structure of the transistor.

The interlayer insulating film 40 is arranged on the main surface 30a so as to cover the gate 35 and the sidewall spacer 36. The interlayer insulating film 40 is made of, for example, silicon oxide. The contact plug 51, the contact plug 52, the contact plug 53, the contact plug 54, the contact plug 55, the contact plug 56, the contact plug 57, the contact plug 58, and the contact plug 59 are embedded in a contact hole formed in the interlayer insulating film 40. The contact plug 51, the contact plug 52, the contact plug 53, the contact plug 54, the contact plug 55, the contact plug 56, the contact plug 57, the contact plug 58, and the contact plug 59 are made of, for example, tungsten (W).

The polysilicon layer 31 has an end portion 31b which is an end portion on one side (lower side in FIG. 2) in the second direction DR2, and an end portion 31c which is an end portion on the other side (upper side in FIG. 2) in the second direction DR2. The polysilicon layer 32 has an end portion 32b which is an end portion on one side in the second direction DR2, and an end portion 32c which is an end portion on the other side in the second direction DR2.

The lower end of the contact plug 51 is electrically connected to the upper end of the polysilicon layer 31 at the end portion 31b. The lower end of the contact plug 52 is electrically connected to the upper end of the polysilicon layer 31 at the end portion 31c. The lower end of the contact plug 53 is electrically connected to the upper end of the polysilicon layer 32 at the end portion 32b. The lower end of the contact plug 54 is electrically connected to the upper end of the polysilicon layer 32 at the end portion 32c.

The lower end of the contact plug 55 is electrically connected to the upper end of the polysilicon layer 31 between the end portions 31b and 31c. The lower end of the contact plug 56 is electrically connected to the upper end of the polysilicon layer 32 at the end portions 32b and 32c. From another point of view, the contact plugs 51 and 52 are located on one side and the other side of the contact plug 55 in the second direction DR2, respectively, and the contact plugs 53 and 54 are located on one side and the other side of the contact plug 56 in the second direction DR2, respectively.

The lower end of the contact plug 57 and the lower end of the contact plug 58 are electrically connected to the source region 30f (second portion 30fb) and the drain region 30g (second portion 30gb), respectively. The lower end of the contact plug 59 is electrically connected to the gate 35.

The wiring 71, the wiring 72, the wiring 73, the wiring 74, the wiring 75, the wiring 76, and the wiring 77 are arranged on the interlayer insulating film 40. The wiring 71, the wiring 72, the wiring 73, the wiring 74, the wiring 75, the wiring 76, and the wiring 77 are made of, for example, aluminum or aluminum alloy. The wiring 71 is electrically connected to the upper end of the contact plug 51 and the upper end of the contact plug 54. The wiring 72 is electrically connected to the upper end of the contact plug 52 and the upper end of the contact plug 54. The wiring 71 and the wiring 72 are electrically connected to the resistance measurement circuit 22 (see FIG. 1).

The wiring 73 and the wiring 74 are electrically connected to the upper end of the contact plug 55 and the upper end of the contact plug 56, respectively. The wiring 73 and the wiring 74 are electrically connected to the power supply circuit 21 (see FIG. 1). The wiring 75, the wiring 76, and the wiring 77 are electrically connected to the upper end of the contact plug 57, the upper end of the contact plug 58, and the upper end of the contact plug 59, respectively.

### <Operation of Semiconductor Device 100>

The operation of the semiconductor device 100 will be described below.

A current is supplied from the power supply circuit 21 to the polysilicon layer 31 via the wiring 73 and the contact plug 54. This current flows downward through the polysilicon layer 31 (see the solid line arrow in FIG. 4). The current that has reached the diffusion layer 30c flows toward the polysilicon layer 32 (see the solid line arrow in FIG. 4). The current that has reached the polysilicon layer 32 flows upward in the polysilicon layer 32 (see the solid line arrow in FIG. 5).

When an external magnetic field is parallel to the main surface 30a (in the example shown in FIG. 4, a direction of the external magnetic field is along the first direction DR1), a path of the current flowing downward through the polysilicon layer 31 and a path of the current flowing upward through the polysilicon layer 32 are bent under the Lorentz force from the magnetic field (see the dotted arrows in FIGS. 4 and 5). This bending of the current paths changes the resistance value of the polysilicon layer 31 and the resistance value of the polysilicon layer 32. A change in the resistance value of the polysilicon layer 31 and a change in the resistance value of the polysilicon layer 32 are detected by the resistance measurement circuit 22, and predetermined calculations are performed by the signal processing circuit 23, whereby the external magnetic field applied to the semiconductor device 100 is detected.

### <Method of Manufacturing Semiconductor Device 100>

A method of manufacturing the semiconductor device 100 will be described below.

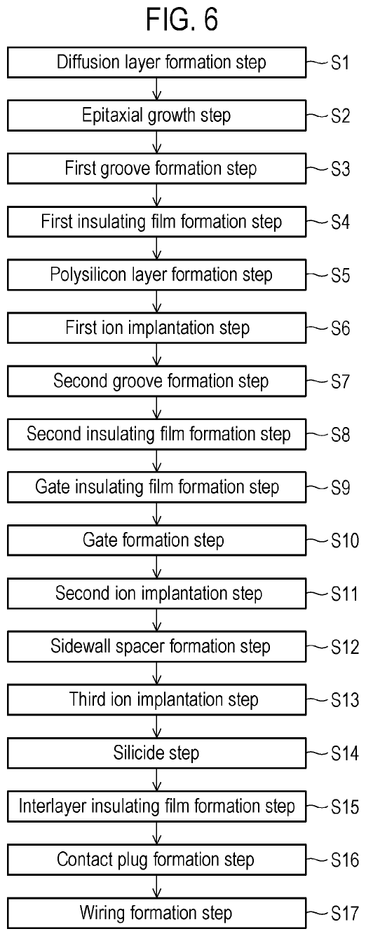

FIG. 6 is a diagram showing a process of manufacturing the semiconductor device 100. As shown in FIG. 6, the method of manufacturing the semiconductor device 100 includes a diffusion layer formation step S1, an epitaxial growth step S2, a first groove formation step S3, a first insulating film formation step S4, a polysilicon layer formation step S5, a first ion implantation step S6, a second groove formation step S7, a second insulating film formation step S8, a gate insulating film formation step S9, a gate formation step S10, a second ion implantation step S11, a sidewall spacer formation step S12, and a third ion implantation step S13. The method of manufacturing the semiconductor device 100 further includes a silicide step S14, an interlayer insulating film formation step S15, a contact plug formation step S16, and a wiring formation step S17.

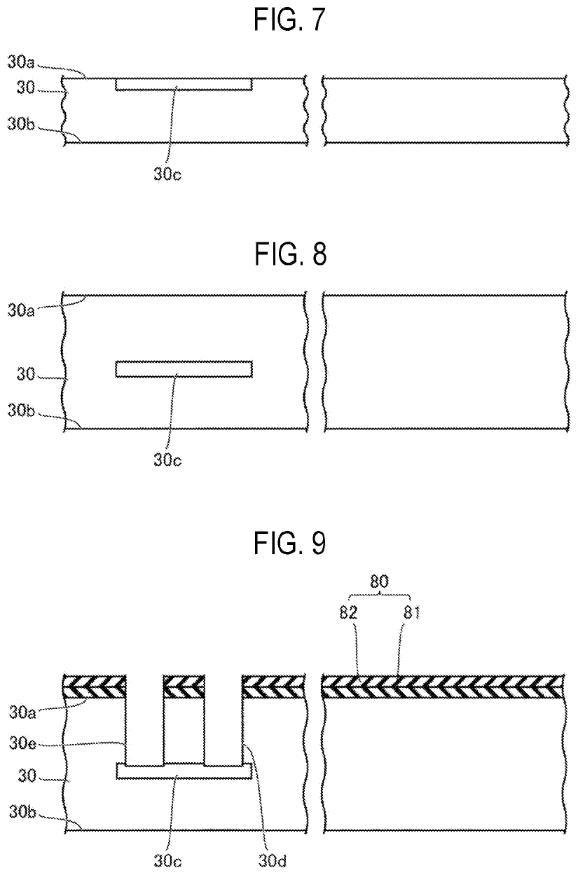

FIG. 7 is a cross-sectional view for explaining the diffusion layer formation step S1. As shown in FIG. 7, in the diffusion layer formation step S1, a diffusion layer 30c is formed on the main surface 30a. The diffusion layer 30c is formed by performing ion implantation on the main surface 30a and thermally diffusing the impurity introduced by ion implantation through annealing. Further, the impurity may be coated instead of the ion implantation.

FIG. 8 is a cross-sectional view for explaining the epitaxial growth step S2. In the epitaxial growth step S2, as shown in FIG. 8, the semiconductor substrate 30 is epitaxially grown on the main surface 30a. The epitaxial growth of the semiconductor substrate 30 is performed by, for example, CVD (Chemical Vapor Deposition). As a result, a distance between the main surface 30a and the main surface 30b is increased, and the diffusion layer 30c is located between the main surface 30a and the main surface 30b.

FIG. 9 is a cross-sectional view for explaining the first groove formation step S3. As shown in FIG. 9, grooves 30d and 30e are formed in the first groove formation step S3. In the first groove formation step S3, first, a hard mask 80 is formed on the main surface 30a. The hard mask 80 has, for example, a first layer 81 arranged on the main surface 30a and a second layer 82 arranged on the first layer 81. The first layer 81 and the second layer 82 are made of silicon oxide and silicon nitride, respectively. Second, the hard mask 80 is patterned by performing an etching in which a resist pattern formed of photoresist on the hard mask 80 is used as a mask. Third, grooves 30d and 30e are formed by performing an etching in which the patterned hard mask 80 is used. This etching is performed by anisotropic etching so that the grooves 30d and 30e reach the diffusion layer 30c.

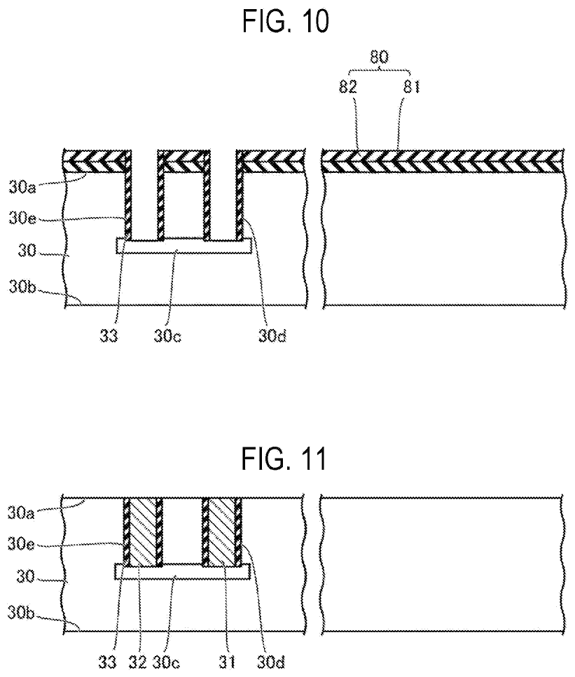

FIG. 10 is a cross-sectional view for explaining the first insulating film formation step S4. In the first insulating film formation step S4, as shown in FIG. 10, an insulating film 33 is formed on the inner wall surfaces of the grooves 30d and 30e. In the first insulating film formation step S4, first, by thermal oxidation, the insulating film 33 is formed on the inner wall surface of the groove 30d, the inner wall surface of the groove 30e, and the diffusion layer 30c exposed from the grooves 30d and 30e. Second, anisotropic etching is performed to remove the insulating film 33 formed on the diffusion layer 30c exposed from the grooves 30d and 30e.

FIG. 11 is a cross-sectional view for explaining the polysilicon layer formation step S5. As shown in FIG. 11, in the polysilicon layer formation step S5, the grooves 30d and 30e are filled with polysilicon layers 31 and 32, respectively. In the polysilicon layer formation step S5, first, impurity-doped polysilicon is embedded in the grooves 30d and 30e by, e.g., CVD. Second, polysilicon protruding from the grooves 30d and 30e is removed by, for example, CMP (Chemical Mechanical Polishing). The polysilicon protruding from the grooves 30d and 30e may be removed by etching-back. Thereafter, the hard mask 80 is removed. As described above, the polysilicon layers 31 and 32 are formed by embedding the impurity-doped polysilicon through CVD. Therefore, the impurity concentrations in the polysilicon layers 31 and 32 are uniform.

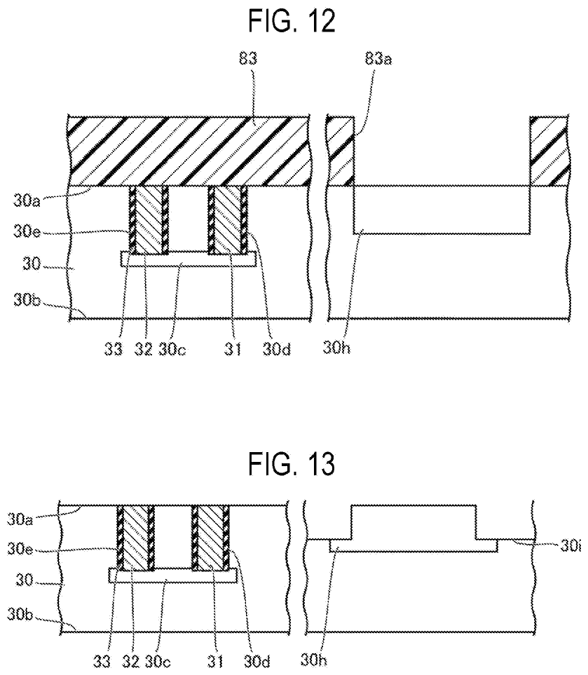

FIG. 12 is a cross-sectional view for explaining the first ion implantation step S6. As shown in FIG. 12, a well region 30h is formed in the first ion implantation step S6. The well region 30h is arranged on the main surface 30a and is formed by performing an ion implantation in which a resist pattern 83 made of photoresist is used as a mask. The resist pattern 83 has an opening 83a, and the well region 30h is formed in the portion of the semiconductor substrate 30 exposed from the opening 83a.

FIG. 13 is a cross-sectional view for explaining the second groove formation step S7. As shown in FIG. 13, in the second groove formation step S7, a groove 30i is formed on the main surface 30a. The groove 30i is formed in a similar manner to the grooves 30d and 30e. FIG. 14 is a cross-sectional view for explaining the second insulating film formation step S8. As shown in FIG. 14, in the second insulating film formation step S8, an insulating film 37 is embedded in the groove 30i. The insulating film 37 is formed by embedding constituent material of the insulating film 37 into the groove 30i by, for example, CVD, and removing the constituent material of the insulating film 37 protruding from the groove 30i by, for example, CMP.

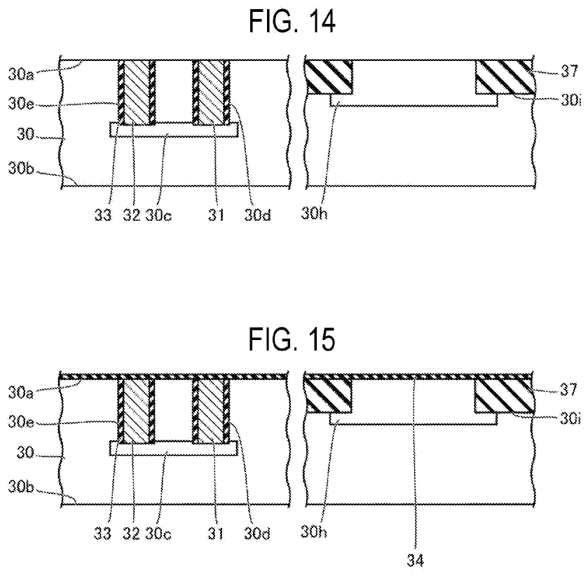

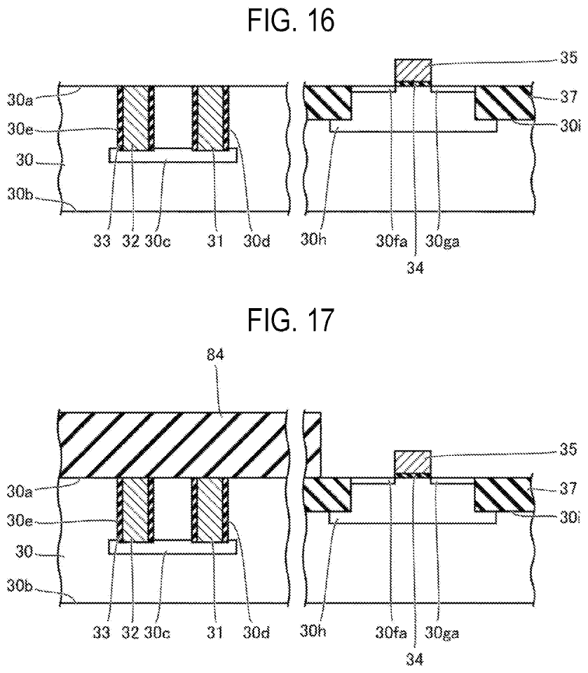

FIG. 15 is a cross-sectional view for explaining the gate insulating film formation step S9. As shown in FIG. 15, in the gate insulating film formation step S9, a gate insulating film 34 is formed on the main surface 30a by, for example, thermal oxidation. FIG. 16 is a cross-sectional view for explaining the gate formation step S10. As shown in FIG. 16, a gate 35 is formed on the gate insulating film 34 in the gate formation step S10. The gate 35 is formed by depositing constituent material of the gate 35 on the gate insulating film 34 by, for example, CVD, and etching the deposited constituent material of the gate 35 using a resist pattern formed of photoresist as a mask.

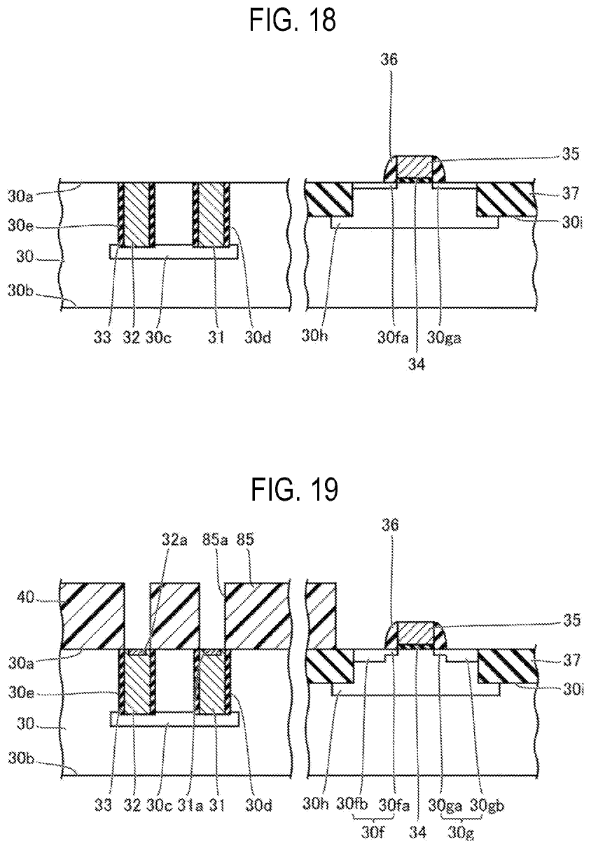

FIG. 17 is a cross-sectional view for explaining the second ion implantation step S11. As shown in FIG. 17, in the second ion implantation step S11, a first portion 30fa and a first portion 30ga are formed by performing ion implantation in which the gate 35, the insulating film 37, and the resist pattern 84 formed of the photoresist are used as a mask. FIG. 18 is a cross-sectional view for explaining the sidewall spacer formation step S12. As shown in FIG. 18, in the sidewall spacer formation step S12, a sidewall spacer 36 is formed on the first portion 30fa and the first portion 30ga so as to be in contact with the gate 35 by depositing constituent material of the sidewall spacer 36 by, for example, CVD, and etching back the deposited constituent material of the sidewall spacer 36.

FIG. 19 is a cross-sectional view for explaining the third ion implantation step S13. As shown in FIG. 19, in the third ion implantation step S13, a second portion 30fb and a second portion 30gb are formed by performing an ion implantation in which the gate 35, the sidewall spacer 36, the insulating film 37, and the resist pattern 85 formed of photoresist are used as a mask. Since the opening 84a is formed in the resist pattern 84 to expose the polysilicon layers 31 and 32, contact regions 31a and 32a are also formed at this time.

In the silicide step S14, the portion of the main surface 30a where the second portion 30fb is formed, the portion of the main surface 30a where the second portion 30gb is formed, the upper surface of the gate 35, the upper end of the polysilicon layer 31, and the upper end of the polysilicon layer 32 are turned into silicide. In the silicide step S14, first, metal material such as titanium or cobalt is deposited on the main surface 30a so as to cover the polysilicon layer 31, the polysilicon layer 32, the gate 35, the sidewall spacer 36, and the insulating film 37. Second, by performing a heat treatment, the deposited metal material reacts with silicon such that the portion of the main surface 30a where the second portion 30fb is formed, the portion of the main surface 30a where the second portion 30gb is formed, the upper surface of the gate 35, the upper end of the polysilicon layer 31, and the upper end of the polysilicon layer 32 are turned into silicide. Thereafter, unreacted metal material is removed by etching.

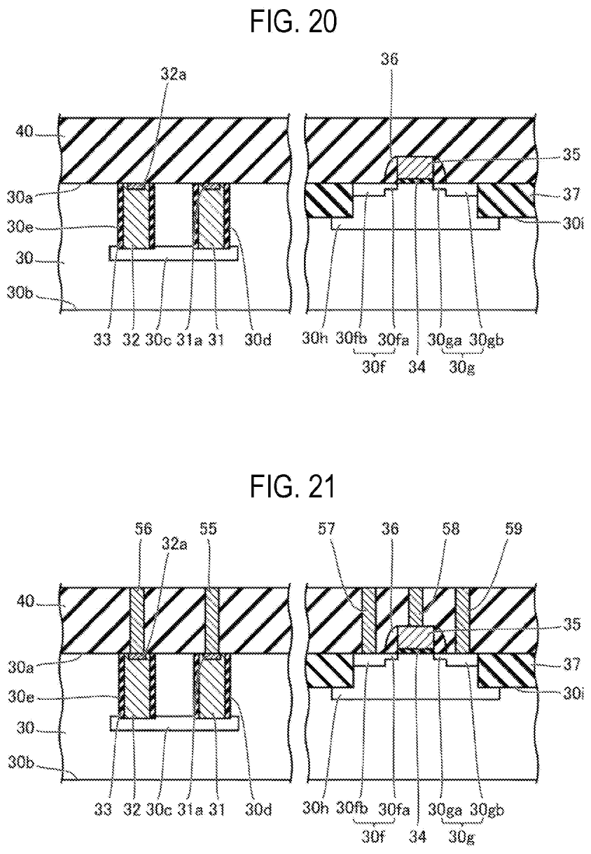

FIG. 20 is a cross-sectional view for explaining the interlayer insulating film formation step S15. As shown in FIG. 20, in the interlayer insulating film formation step S15, an interlayer insulating film 40 is formed on the main surface 30a so as to cover the polysilicon layer 31, the polysilicon layer 32, the gate 35, the sidewall spacer 36, and the insulating film 37. In the interlayer insulating film formation step S15, first, constituent material of the interlayer insulating film 40 is deposited on the main surface 30a by, for example, CVD, so as to cover the polysilicon layer 31, the polysilicon layer 32, the gate 35, the sidewall spacer 36, and the insulating film 37. Second, the deposited constituent material of the interlayer insulating film 40 is planarized by, for example, CMP.

FIG. 21 is a cross-sectional view for explaining the contact plug formation step S16. As shown in FIG. 21, in the contact plug formation step S16, a contact plug 51 (not shown), a contact plug 52 (not shown), a contact plug 53 (not shown), a contact plug 54 (not shown), a contact plug 55, a contact plug 56, a contact plug 57, a contact plug 58, and a contact plug 59 are formed in the interlayer insulating film 40. In the contact plug formation step S16, first, contact holes are formed in the interlayer insulating film 40. The contact holes are formed by performing an anisotropic etching on the interlayer insulating film 40 by using a resist pattern formed of photoresist as a mask. Second, constituent material of the contact plugs is embedded into the contact holes by, for example, CVD. Third, the constituent material of the contact plugs protruding from the contact holes is removed by, for example, CMP.

In the wiring formation step S17, a wiring 71, a wiring 72, a wiring 73, a wiring 74, a wiring 75, a wiring 76, and a wiring 77 are formed. The wiring 71, the wiring 72, the wiring 73, the wiring 74, the wiring 75, the wiring 76, and the wiring 77 are formed by depositing constituent material of these wirings on the interlayer insulating film 40 through, for example, sputtering, and then etching the deposited constituent material by using a resist pattern formed of photoresist. As described above, the semiconductor device 100 having the structure shown in FIGS. 2 to 5 is manufactured.

### <Effects of Semiconductor Device 100>

The effects of the semiconductor device 100 will be described below.

In the semiconductor device 100, the polysilicon layers 31 and 32 are formed by embedding the polysilicon doped with an impurity into the grooves 30d and 30e by, for example, CVD. Therefore, variations in impurity concentration in the polysilicon layers 31 and 32 are small. Accordingly, in the semiconductor device 100, variations in sensitivity of the Hall element 10 are suppressed due to the suppressed variations in impurity concentration in the polysilicon layers 31 and 32.

According to the semiconductor device 100, it is easy to adjust the sensitivity of the Hall element 10. That is, in the semiconductor device 100, the path of the current flowing through the polysilicon layer 31 and the path of the current flowing through the polysilicon layer 32 may be lengthened by increasing the depth of the groove 30d (depth D1) and the depth of the groove 30e (depth D2) (for example, by setting them to 10 μm or more). This makes it possible to enhance the sensitivity of the Hall element 10.

Further, in the semiconductor device 100, the sensitivity of the Hall element 10 may be adjusted by increasing or decreasing the impurity concentrations in the polysilicon layers 31 and 32. The impurity concentrations in the polysilicon layer 31 and the polysilicon layer 32 may be easily adjusted by adjusting a doping amount to the polysilicon when embedding the polysilicon into the grooves 30d and 30e.

In the semiconductor device 100, an area of the Hall element in a plan view may be reduced by narrowing widths and spacing of the grooves 30d and 30e. The widths and spacing of the grooves 30d and 30e are not particularly limited as long as the hard mask 80 can be patterned and the diffusion layer 30c can be exposed from bottoms of the grooves 30d and 30e. Therefore, according to the semiconductor device 100, it is possible to reduce the area of the Hall element 10 in a plan view.

In the semiconductor device 100, when the wiring 71 is electrically connected to the upper end of the polysilicon layer 31 at the end portion 31b and the upper end of the polysilicon layer 32 at the end portion 32c, and the wiring 72 is electrically connected to the upper end of the polysilicon layer 31 at the end portion 31c and the upper end of the polysilicon layer 32 at the end portion 32b, an effect of change in the resistance value due to the magnetic field on the polysilicon layer 31 and an effect of change in the resistance value due to the magnetic field on the polysilicon layer 32 are added together. Accordingly, in this case, it is possible to enhance the sensitivity of the Hall element 10.

### Second Embodiment

A semiconductor device according to a second embodiment of the present disclosure will be described. The semiconductor device according to the second embodiment is referred to as a semiconductor device 200. Points different from the semiconductor device 100 will be mainly described, and the redundant description thereof will not be repeated.

### <Configuration of Semiconductor Device 200>

A configuration of the semiconductor device 200 will be described below.

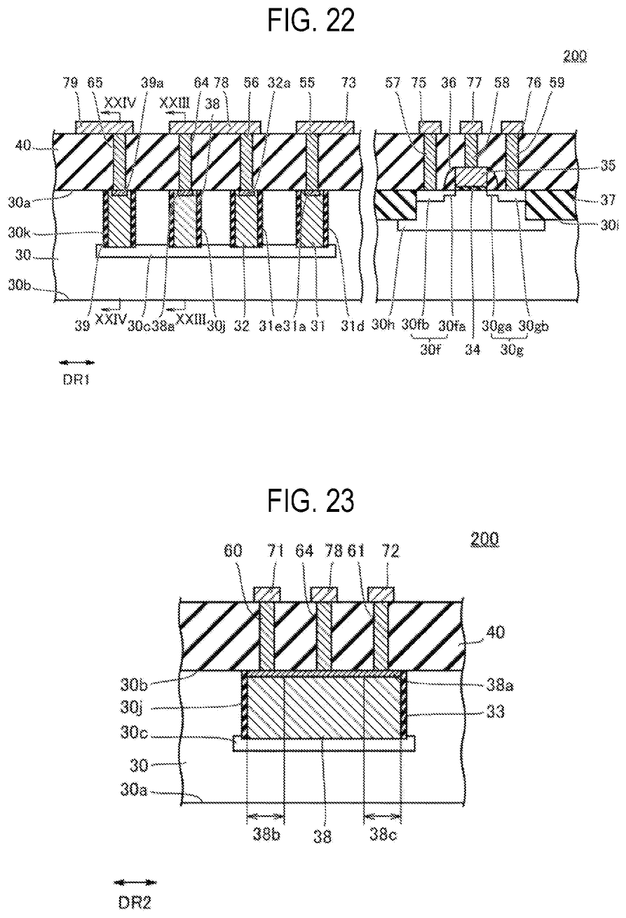

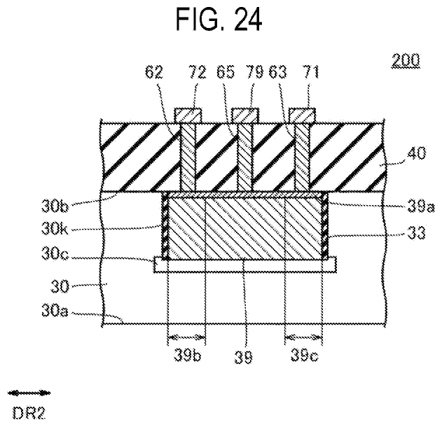

FIG. 22 is a plan view of the semiconductor device 200. FIG. 23 is a cross-sectional view taken along line XXIII-XXIII in FIG. 22. FIG. 24 is a cross-sectional view taken along line XXIV-XXIV in FIG. 22. As shown in FIGS. 22 to 24, the semiconductor device 200 includes a semiconductor substrate 30, a polysilicon layer 31, a polysilicon layer 32, an insulating film 33, a gate insulating film 34, a gate 35, a sidewall spacer 36, and an insulating film 37. The semiconductor device 200 further includes an interlayer insulating film 40, a contact plug 51, a contact plug 52, a contact plug 53, a contact plug 54, a contact plug 55, a contact plug 56, a contact plug 57, a contact plug 58, and a contact plug 59.

The semiconductor device 200 further includes a wiring 71, a wiring 72, a wiring 73, a wiring 75, a wiring 76, and a wiring 77. In relation to these points, the semiconductor device 200 has a configuration in common with the semiconductor device 100.

In the semiconductor device 200, a groove 30j and a groove 30k are further formed on the main surface 30a. The groove 30j and the groove 30k are arranged in a spaced-apart relationship along the first direction DR1. A groove 30e is arranged between the groove 30d and the groove 30j in the first direction DR1, and a groove 30j is arranged between the groove 30e and the groove 30k in the first direction DR1. That is, the grooves 30d, 30e, 30j, and 30k are arranged at intervals in the named order along the first direction DR1. The grooves 30j and 30k extend along the second direction DR2. The grooves 30j and 30k extend toward the main surface 30b so as to reach the diffusion layer 30c in a cross-sectional view orthogonal to the second direction DR2.

The semiconductor device 200 further includes a polysilicon layer 38 and a polysilicon layer 39. The impurity concentration is uniform in the polysilicon layers 38 and 39 (that is, the minimum and maximum impurity concentrations are 0.8 times or more and 1.2 or less of the average impurity concentration, respectively). The polysilicon layer 38 and the polysilicon layer 39 are embedded in the groove 30j and the groove 30k, respectively. The insulating film 33 is interposed between the polysilicon layer 38 and the inner wall surface of the groove 30j and between the polysilicon layer 39 and the inner wall surface of the groove 30k. The lower end of the polysilicon layer 38 and the lower end of the polysilicon layer 39 are electrically connected to the diffusion layer 30c.

A contact region 38a and a contact region 39a are formed at the upper end of the polysilicon layer 38 and the upper end of the polysilicon layer 39, respectively. The polysilicon layer 38 has an end portion 38b which is one end portion in the second direction DR2, and an end portion 38c which is the other end portion in the second direction DR2. The polysilicon layer 39 has an end portion 39b which is one end portion in the second direction DR2, and an end portion 39c which is the other end portion in the second direction DR2.

The semiconductor device 200 further includes a contact plug 60, a contact plug 61, a contact plug 62, a contact plug 63, a contact plug 64, and a contact plug 65. The contact plug 60, the contact plug 61, the contact plug 62, the contact plug 63, the contact plug 64, and the contact plug 65 are arranged in the interlayer insulating film 40. The lower end of the contact plug 60 is electrically connected to the upper end of the polysilicon layer 38 at the end portion 38b, and the lower end of the contact plug 61 is electrically connected to the upper end of the polysilicon layer 38 at the end portion 38c. The lower end of the contact plug 62 is electrically connected to the upper end of the polysilicon layer 39 at the end portion 39b, and the lower end of the contact plug 63 is electrically connected to the upper end of the polysilicon layer 39 at the end portion 39c.

The lower end of the contact plug 64 is electrically connected to the upper end of the polysilicon layer 38 between the end portion 38b and the end portion 38c, and the lower end of the contact plug 65 is electrically connected to the upper end of the polysilicon layer 39 between the end portion 39b and the end portion 39c. The contact plug 60, the contact plug 61, the contact plug 62, the contact plug 63, the contact plug 64, and the contact plug 65 are made of, for example, tungsten.

In the semiconductor device 200, the wiring 71 is electrically connected to the upper ends of the contact plugs 60 and 63 in addition to the upper ends of the contact plugs 51 and 54. In the semiconductor device 200, the wiring 72 is electrically connected to the upper ends of the contact plugs 61 and 62 in addition to the upper ends of the contact plugs 52 and 53. The semiconductor device 200 includes a wiring 78 instead of the wiring 74, and further includes a wiring 79. The wiring 78 is electrically connected to the upper end of the contact plug 56 and the upper end of the contact plug 64. Therefore, the upper end of the polysilicon layer 31 and the upper end of the polysilicon layer 32 are electrically connected to each other. The wiring 79 is electrically connected to the upper end of the contact plug 65.

In the semiconductor device 200, the wirings 73 and 79 are electrically connected to the power supply circuit 21. As a result, the current flowing through the polysilicon layer 31, the diffusion layer 30c, and the polysilicon layer 32 is supplied to the polysilicon layer 38 via the wiring 78. This current flows downward through the polysilicon layer 38, and then flows through the diffusion layer 30c to reach the polysilicon layer 39. This current flows upward through the polysilicon layer 39. A path of this current is bent under the Lorentz force from an external magnetic field parallel to the main surface 30a. In relation to these points, the configuration of the semiconductor device 200 is different from the configuration of the semiconductor device 100.

In the above-described examples, the number of polysilicon layers and the number of grooves in which the polysilicon layers are embedded are four. However, the number of polysilicon layers and the number of grooves in which the polysilicon layers are embedded are not limited thereto.

### <Method of Manufacturing Semiconductor Device 200>

A method of manufacturing the semiconductor device 200 will be described below.

Similar to the method of manufacturing the semiconductor device 100, the method of manufacturing the semiconductor device 200 includes a diffusion layer formation step S1, an epitaxial growth step S2, a first groove formation step S3, a first insulating film formation step S4, a polysilicon layer formation step S5, a first ion implantation step S6, a second groove formation step S7, a second insulating film formation step S8, a gate insulating film formation step S9, a gate formation step S10, a second ion implantation step S11, a sidewall spacer formation step S12, a third ion implantation step S13, a silicide step S14, an interlayer insulating film formation step S15, a contact plug formation step S16, and a wiring formation step S17.

In the method of manufacturing the semiconductor device 200, in the first groove formation step S3, a groove 30j and a groove 30k are formed in addition to the groove 30d and the groove 30e. In the method for manufacturing the semiconductor device 200, in the polysilicon layer formation step S5, the polysilicon layer 38 and the polysilicon layer 39 are embedded in the groove 30j and the groove 30k, respectively, in addition to embedding the polysilicon layer 31 in the groove 30d and embedding the polysilicon layer 32 in the groove 30e. In the method of manufacturing the semiconductor device 200, in the third ion implantation step S13, a contact region 38a and a contact region 39a are further formed in addition to the second portion 30fb, the second portion 30gb, the contact region 31a, and the contact region 32a.

In the method of manufacturing the semiconductor device 200, in the silicide step S14, the upper end of the polysilicon layer 38 and the upper end of the polysilicon layer 39 are turned into silicide, in addition to the portion of the main surface 30a where the second portion 30fb is formed, the portion of the main surface 30a where the second portion 30gb is formed, the upper surface of the gate 35, the upper end of the polysilicon layer 31, and the upper end of the polysilicon layer 32.

Further, in the method of manufacturing the semiconductor device 200, in the contact plug formation step S16, a contact plug 60, a contact plug 61, a contact plug 62, a contact plug 63, a contact plug 64, and a contact plug 65 are formed in addition to the contact plug 51, the contact plug 52, the contact plug 53, the contact plug 54, the contact plug 55, the contact plug 56, the contact plug 57, the contact plug 58, and the contact plug 59. In the method of manufacturing the semiconductor device 200, in the wiring formation step S17, a wiring 78 and a wiring 79 are formed in addition to the wiring 71, the wiring 72, the wiring 73, the wiring 75, the wiring 76, and the wiring 77. In relation to these points, the method of manufacturing the semiconductor device 200 differs from the method of manufacturing the semiconductor device 100.

### <Effect of Semiconductor Device 200>

The effects of the semiconductor device 200 will be described below.

In the semiconductor device 200, the current also flows through the polysilicon layer 38 and the polysilicon layer 39 in addition to the polysilicon layer 31 and the polysilicon layer 32. Therefore, the current path becomes longer. As a result, according to the semiconductor device 200, the effect of the Lorentz force that the current receives from the external magnetic field parallel to the main surface 30a is further increased, and the sensitivity of the Hall element 10 is further enhanced.

According to the semiconductor device of the present disclosure, it is possible to suppress variations in sensitivity of a vertical Hall element.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor substrate having a first main surface and a second main surface; and
a first polysilicon layer and a second polysilicon layer doped with an impurity,
wherein the semiconductor substrate includes a diffusion layer doped with an impurity,
wherein the diffusion layer is located between the first main surface and the second main surface,
wherein a first groove and a second groove are formed on the first main surface in a spaced-apart relationship along a first direction in a plan view,
wherein each of the first groove and the second groove extends along a second direction orthogonal to the first direction in a plan view and extends toward the second main surface so as to reach the diffusion layer in a cross-sectional view orthogonal to the second direction,
wherein the first polysilicon layer and the second polysilicon layer are embedded in the first groove and the second groove, respectively, and
wherein a lower end of the first polysilicon layer and a lower end of the second polysilicon layer are electrically connected to each other by the diffusion layer.

2. The semiconductor device of claim 1, wherein in each of the first polysilicon layer and the second polysilicon layer, minimum and maximum impurity concentrations are 0.8 times or more and 1.2 times or less an average impurity concentration, respectively.

3. The semiconductor device of claim 1, further comprising:
an interlayer insulating film arranged on the first main surface;
a first contact plug, a second contact plug, a third contact plug, a fourth contact plug, a fifth contact plug, and a sixth contact plug arranged in the interlayer insulating film; and
a first wiring and a second wiring,
wherein a lower end of the first contact plug, a lower end of the second contact plug, and a lower end of the fifth contact plug are electrically connected to an upper end of the first polysilicon layer,
wherein a lower end of the third contact plug, a lower end of the fourth contact plug, and a lower end of the sixth contact plug are electrically connected to an upper end of the second polysilicon layer,
wherein the first contact plug and the second contact plug are located on one side and the other side of the fifth contact plug in the second direction, respectively,
wherein the third contact plug and the fourth contact plug are located on one side and the other side of the sixth contact plug in the second direction, respectively,
wherein the first wiring is electrically connected to the first contact plug and the fourth contact plug,
wherein the second wiring is electrically connected to the second contact plug and the third contact plug, and
wherein a current flowing into the first polysilicon layer from the first contact plug flows through the diffusion layer and the second polysilicon layer and flows out of the second contact plug.

4. The semiconductor device of claim 1, wherein a depth of the first groove and a depth of the second groove are 10 μm or more and 30 μm or less.

5. The semiconductor device of claim 1, further comprising:
a third polysilicon layer and a fourth polysilicon layer doped with an impurity,
wherein a third groove and a fourth groove spaced apart from each other along the first direction are formed on the first main surface,
wherein the second groove is located between the first groove and the third groove in the first direction,
wherein the third groove is located between the second groove and the fourth groove in the first direction,
wherein each of the third groove and the fourth groove extends along the second direction, and extends toward the second main surface so as to reach the diffusion layer in the cross-sectional view orthogonal to the second direction,
wherein the third polysilicon layer and the fourth polysilicon layer are embedded in the third groove and the fourth groove, respectively,
wherein a lower end of the third polysilicon layer and a lower end of the fourth polysilicon layer are electrically connected to each other by the diffusion layer, and
wherein an upper end of the second polysilicon layer and an upper end of the third polysilicon layer are electrically connected to each other.
